(19) United States
(12) Patent Application Publication
(10) Pub. No.: US 2011/0143460 A1
(43) Pub. Date: Jun. 16, 2011

(54) METHOD OF MANUFACTURING MAGNETORESISTANCE ELEMENT AND STORAGE MEDIUM USED IN THE MANUFACTURING METHOD

(75) Inventors: Koji Tsunekawa, Kawasaki-shi (JP); Yoshinori Nagamine, Kawasaki-shi (JP); Shinji Yamagata, Kawasaki-shi (JP)

(73) Assignee: CANON ANELVA CORPORATION, Kawasaki-shi (JP)

(21) Appl. No.: 13/059,464

(22) PCT Filed: Aug. 31, 2009
(86) PCT No.: PCT/JP2009/004249

§ 371 Date: Feb. 17, 2011

(30) Foreign Application Priority Data
Sep. 9, 2008 (JP) 2008-231087

(51) Int. Cl. H01L 21/02

(52) U.S. Cl. 438/3; 257/E21.002

(57) ABSTRACT

An embodiment of the invention provides a method of manufacturing a magnetoresistance element with an MR ratio higher than that of the related art.

A method of manufacturing a magnetoresistance element includes a step of forming a magnetization fixed layer, a magnetization free layer, and a tunnel barrier layer provided between the magnetization fixed layer and the magnetization free layer on a substrate. In the method, the tunnel barrier layer is formed by arranging a target that has a diameter smaller than that of the substrate, contains a magnesium oxide sintered body, and has a relative density 90% or more so as to be inclined with respect to a surface to be deposited of the substrate, and forming a magnesium oxide layer using a sputtering method while rotating the substrate.

### TECHNICAL FIELD

The present invention relates to a magnetoresistance element used in a magnetic reproducing head of a magnetic disk driving device, a storage element of a magnetic random access memory, and a magnetic sensor, and more particularly, to a tunneling magnetoresistance element (particularly, a spin-valve tunneling magnetoresistance element). In addition, the present invention relates to a method of manufacturing a magnetoresistance element and a storage medium used in the manufacturing method.

### BACKGROUND ART

Patent Literatures 1 to 6 and Non-patent Literatures 1 and 2 disclose TMR (tunneling magnetoresistance) elements each having a tunnel barrier layer and first and second ferromagnetic layers that are provided on both sides of the tunnel barrier layer. The first and/or second ferromagnetic layers of the element are made of an alloy (hereinafter, a CoFeB alloy) containing Co atoms, Fe atoms, and B atoms. In addition, the CoFeB alloy layer has a polycrystalline structure.

Patent Literatures 2 to 5, Patent Literature 7, and Non-patent Literatures 1 to 5 disclose TMR elements which use a monocrystalline or polycrystalline magnesium oxide film as a tunnel barrier film.

### [Related Art Document]

### [Patent Literature]

[Patent Literature 1] Japanese Patent Application Laid-Open No. 2002-204004

[Patent Literature 2] WO2005/088745 [Patent Literature 3] Japanese Patent Application Laid-Open No. 2003-304010

[Patent Literature 4] Japanese Patent Application Laid-Open No. 2006-080116

[Patent Literature 5] U.S. Patent Application Publication No. 2006/0056115

[Patent Literature 6] U.S. Pat. No. 7,252,852

[Patent Literature 7] Japanese Patent Application Laid-Open No. 2003-318465

### [Non-patent Literature]

[Non-patent Literature 1] D. D. Djayaprawira et al., ‘Applied Physics Letters’, 86, 092502 (2005)

[Non-patent Literature2] Shinji Yuasa et al., ‘Japanese Journal of Applied Physics’, Vol. 43, No. 48, pp. 588-590, Published on Apr. 2, 2004

[Non-patent Literature 3] C. L. Platt et al., ‘J. Appl. Phys.’ 81(8), Apr. 15, 1997

[Non-patent Literature 4] W. H. Butler et al., ‘The American Physical Society’ (Physical Review Vol. 63, 054416) Jan. 8, 2001

[Non-patent Literature 5] S. P. Parkin et al., ‘2004 Nature Publishing Group’ Letters, pp. 862-887, Published on Oct. 31, 2004

### DISCLOSURE OF THE INVENTION

### Problem to be Solved by the Invention

An object of the invention is to provide a method of manufacturing a magnetoresistance element with an MR ratio higher than that of the related art and a storage medium used in the manufacturing method.

### Means for Solving the Problem

According to a first aspect of the invention, there is provided a method of manufacturing a magnetoresistance element. The method includes a step of forming a magnetization fixed layer, a magnetization free layer, and a tunnel barrier layer provided between the magnetization fixed layer and the magnetization free layer on a substrate using a sputtering method. The step of forming the tunnel barrier layer includes a step of forming a crystalline magnesium oxide layer by the sputtering method using a target which contains a magnesium oxide sintered body and has a relative density of 90% or more.

According to a second aspect of the invention, there is provided a storage medium that stores a control program for manufacturing a magnetoresistance element using a step of forming a magnetization fixed layer, a magnetization free layer, and a tunnel barrier layer provided between the magnetization fixed layer and the magnetization free layer on a substrate using a sputtering method. The step of forming the tunnel barrier layer executed by the control program includes a step of forming a crystalline magnesium oxide layer by the sputtering method using a target which contains a magnesium oxide sintered body and has a relative density of 90% or more.

The above-mentioned aspects of the invention have the following preferable structures.

The relative density of the target may be in the range of 95.0% to 99.9%.

In the step of forming the tunnel barrier layer, the diameter of the target maybe smaller than that of the substrate. The target and the substrate may be arranged such that a normal line passing through the center of the target intersects a normal line passing through the center of the substrate, and the crystalline magnesium oxide layer may be formed by the sputtering method while the substrate is rotated.

In the step of forming the tunnel barrier layer, the substrate may be rotated at a rotational speed of 30 rpm or more.

In the step of forming the tunnel barrier layer, the substrate may be rotated at a rotational speed of 50 rpm to 500 rpm.

In the step of forming the tunnel barrier layer, the normal line passing through the center of the target may intersect the normal line passing through the center of the substrate at an angle of 1° to 60°.

In the step of forming the tunnel barrier layer, the normal line passing through the center of the target may intersect the normal line passing through the center of the substrate at an angle of 5° to 45°.

In the step of forming the tunnel barrier layer, the radius D of the target and the radius d of the substrate may satisfy 0.01 d≦D≦0.90 d.

In the step of forming the tunnel barrier layer, the radius D of the target and the radius d of the substrate may satisfy 0.10 d≦D≦0.50 d.

In the step of forming the tunnel barrier layer, a line extending in the plane direction of the substrate may intersect the normal line passing through the center of the target at a position that is away from the center of the substrate.

In the step of forming the tunnel barrier layer, the line extending in the plane direction of the substrate may intersect the normal line passing through the center of the target at a position that is away from the outer circumference of the substrate.

### Effect of the Invention

According to the exemplary embodiment of the invention, it is possible to significantly improve the MR ratio of the tunneling magnetoresistance element (hereinafter, referred to as a TMR element) according to the related art. In addition, the invention can be mass-produced and has high practicality. Therefore, according to the exemplary embodiment of the invention, it is possible to provide a memory element of an ultra-large-scale integration MRAM (magnetoresistive random access memory) with high efficiency.

### BRIEF DESCRIPTION OF THE DRAWINGS

FIG. 1 is a cross-sectional view schematically illustrating an example of a sputtering apparatus used to form a MgO layer in the invention.

FIG. 2 is a cross-sectional view schematically illustrating an example of a magnetoresistance element manufactured in the invention.

FIG. 3 is a perspective view schematically illustrating the columnar crystal structure of the magnetoresistance element manufactured in the invention.

FIG. 4 is a diagram schematically illustrating an example of the structure of a film forming apparatus that manufactures the magnetoresistance element according to the invention.

### BEST MODE FOR CARRYING OUT THE INVENTION

A first aspect of the invention provides a method of manufacturing a magnetoresistance element. The magnetoresistance element manufactured by the method according to the exemplary embodiment of the invention includes a magnetization fixed layer, a tunnel barrier layer, and a magnetization free layer formed on a substrate.

The manufacturing method according to the exemplary embodiment of the invention is characterized in that, in a step of forming a tunnel barrier layer, a crystalline MgO layer is formed using a magnesium oxide (hereinafter, referred to as MgO) sintered body with a relative density of 90% or more.

Hereinafter, exemplary embodiments of the invention will be described in detail.

In the following description, a magnesium oxide is referred to as MgO, a cobalt-iron-boron alloy is referred to as CoFeB, a nickel-iron-boron alloy is referred to as NiFeB, a cobalt-iron alloy is referred to as CoFe, and a platinum-manganese alloy is referred to as PtMn.

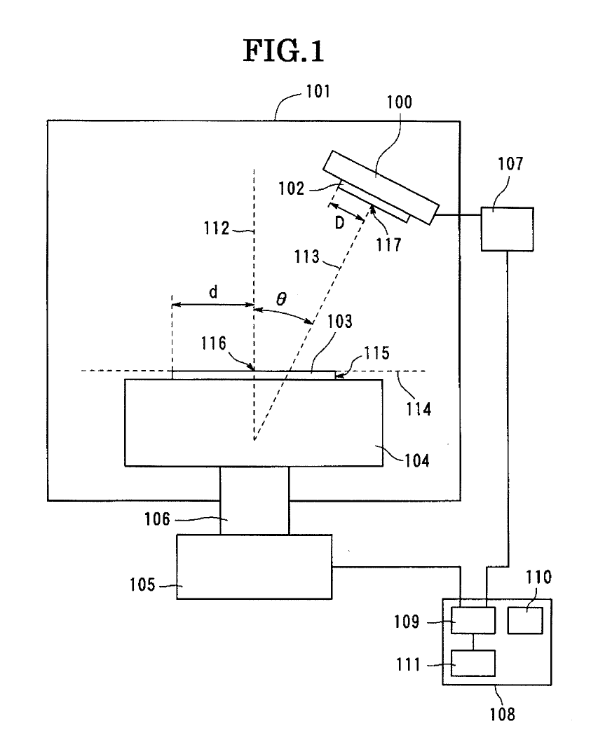

FIG. 1 is a cross-sectional view schematically illustrating an example of a sputtering apparatus that is used to form the tunnel barrier layer in the manufacturing method according to the exemplary embodiment of the invention.

In the apparatus shown in FIG. 1, a sputtering cathode 100 is provided on the ceiling of a sputtering deposition chamber 101, and a target 102 is attached to the sputtering cathode 100. The sputtering cathode 100 is obliquely attached to the ceiling. A substrate support holder 104 that can be rotated by a rotating mechanism 105 and a rotating shaft 106 is provided at the center of the bottom of the sputtering deposition chamber 101, and a substrate 103 is horizontally mounted on the substrate support holder 104. Therefore, the substrate 103 is rotated in the plane with the rotation of the substrate support holder 104 during deposition. The rotational speed V of the substrate support holder 104 may be set to a constant value. In addition, the rotational speed V may be set to a variable value. For example, the rotational speed V is changed from an initial low speed (V1) to a high speed (V2) or from an initial high speed (V2) to a low speed (V1). In addition, the rotational speed V of the substrate support holder 104 may vary as a linear function or a quadratic function.

In the invention, the target 102 used to form the tunnel barrier layer is a MgO sintered body with a relative density of 90% or more, preferably, in the range of 95.0% to 99.9%.

The relative density may be calculated by dividing the sintered density measured based on ‘JIS (Japanese Industrial Standards)—R1634′ using Archimedes’ principle by a theoretical density. In this case, the theoretical density of MgO is 3.585 g/cm³.

The MgO sintered body is produced as follows. For example, first, 1 mass % to 10 mass % of MgO powder is added to a binder, such as polyethylene glycol, and the mixture is dispersed in an ethanol dispersion liquid to produce slurry. The average grain diameter of the MgO powder is in the range of 0.01 μm to 50 μm, preferably, in the range of 0.1 μm to 10 μm. The slurry is wet-mixed by a ball mill for 20 hours or more and is then dried. Then, the dried powder is baked at a high temperature and a high pressure for several hours. The baking temperature is preferably in the range of 1000° C. to 2000° C., the baking pressure is preferably in the range of 1000 Kg/cm2 to 2000 Kg/cm2, and the baking time is preferably in the range of 1 hour to 10 hours.

It is possible to appropriately select the relative density of the sintered body by appropriately selecting the baking temperature, the baking pressure, and the baking time from the baking conditions. For example, the relative density of the sintered body obtained under the baking conditions of 1500° C., 1500 Kg/cm², and 3 hours is 99.8% and is more than the relative density (95.5% ) of the sintered body obtained under the baking conditions of 1200° C., 1200 Kg/cm2, and 1 hour.

The MgO sintered body used in the invention may contain various kinds of minor components. For example, the MgO sintered body may contain 10 ppm to 100 ppm of Zn atoms, C atoms, Al atoms, and Ca atoms. The content of B atoms in the MgO sintered body may be in the range of 1 atomic % to 50 atomic %, preferably, in the range of 10 atomic % to 25 atomic %.

A normal line (hereinafter, referred to as a central normal line) 113 passing through the center 117 of the target 102 is inclined at an angle θ with respect to a normal line (hereinafter, referred to as a central normal line) 112 passing through the center 116 of the upper surface (the surface to be deposited) of the substrate 103 that is horizontally arranged on the lower side. The angle θ is preferably in the range of 1° to 60°, more preferably, in the range of 5° to 45°. Therefore, particles sputtered from the target 102 to the substrate 103 are obliquely incident on the substrate 103.

In the invention, the target 102 and the substrate 103 may be arranged such that the central normal line 113 of the target 102 and a line 114 extending in the plane direction of the surface to be deposited of the substrate 103 intersect each other at a position that is away from the center 116 of the substrate 103.

In the invention, it is preferable that the substrate and the target be arranged such that the central normal line 113 of the target 102 and the line 114 extending in the plane direction of the surface to be deposited of the substrate 103 intersect each other at a position that is away from the outer circumference 115 of the substrate 103. In this case, it is preferable that the intersection position be disposed in the range from the outer circumference 115 of the substrate 103 close to the target 102 to at most half the radius of the substrate 103. That is, the intersection position is disposed in the range of a radius d to d×1.5 from the center 116 of the substrate 103.

In the invention, the target 102 and the substrate 103 may be prepared such that the radius D of the target 102 and the radius d of the substrate 103 preferably satisfy 0.01 d≦D ≦0.90d, more preferably, 0.10 d≦D≦0.50 d.

In the invention, as described above, when the target 102 with a radius smaller than that of the substrate 103 is used, a film forming process is formed while the driving motor 105 is driven to rotate the substrate support holder 104 and the rotating shaft 106, thereby rotating the substrate 103. In this case, the rotational speed of the substrate 103 is preferably 30 rpm or more, more preferably, in the range of 50 rpm to 500 rpm.

In the invention, as described above, the target 102 with a radius smaller than that of the substrate 103 is used. Therefore, it is possible to reduce the size of an apparatus and obtain the performance equal to or better than that of the TMR element formed using a target with a diameter equal to or larger than that of the substrate. In particular, in the invention, the reduction in the size of an apparatus makes it possible to reduce power for exhaustion or power for generating plasma.

In the apparatus shown in FIG. 1, a DC power supply (not shown) of a power supply mechanism 107 applies a predetermined DC power (for example, 1 W to 1000 W, preferably, 10 W to 300 W) to the sputtering cathode 100 holding the target 102. Instead of the DC power supply, an RF power supply may be used as the power supply unit.

Preferably, a shutter mechanism (not shown) that is opened or closed at an arbitrary timing is provided between the target 102 and the substrate 103. In this way, even when power is supplied to the target 102 and sputter particles are emitted from the target 102, it is possible to limit the deposition of the sputter particles on the substrate using an closing operation of the opening and closing operations of the shutter mechanism.

A computer 108 that controls the operation of the sputtering apparatus includes a CPU (central processing unit) 111, a storage medium 110 that stores a control program, and an input/output unit 109. A general-purpose computer with a predetermined performance may be used as the computer 108. Various kinds of storage media using nonvolatile memories, such as a hard disk medium, a magneto-optical disk medium, a floppy (registered trademark) disk medium, a flash memory, and an MRAM used by the general-purpose computer, maybe used as the storage medium 110.

In the invention, the storage media mean all kinds of media capable of storing programs and include so-called recording media. For example, the storage media include all kinds of nonvolatile memories, such as a hard disk medium, a magneto-optical disk medium, a floppy disk medium, a flash memory, and an MRAM.

The storage medium 110 stores a control program for executing a process of sputtering the target 102, which is a MgO sintered body with a relative density of 90% or more, in the sputtering deposition chamber 101 shown in FIG. 1 and depositing sputter particles on the substrate 103.

In the computer 108 used in the invention, digital data for program control stored in the storage medium 110 is temporarily stored in the CPU 111. The CPU 111 performs a calculation process based on the control program, and control signals are transmitted from the input/output unit 109 to the rotating mechanism 105, such as a driving motor, and the power supply unit 107. The operation of a rotation control mechanism (not shown) connected to the rotating mechanism 105, such as a driving motor, is controlled by the control signals, thereby controlling the rotational speed of the rotating mechanism 105, such as a driving motor. In addition, a power control mechanism (not shown) connected to the power supply unit 107 is controlled by the control signals from the input/output unit 109, thereby

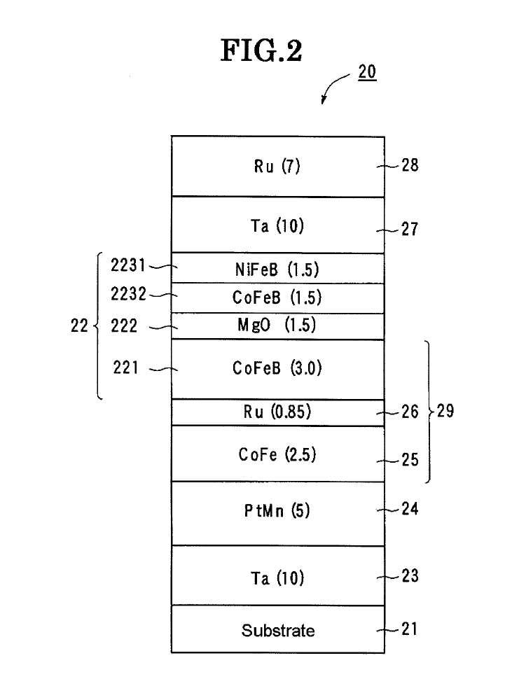

FIG. 2 is a diagram illustrating an example of the laminated structure of a magnetoresistance element 20 including a TMR element 22 manufactured by the manufacturing method according to the exemplary embodiment of the invention. In the magnetoresistance element 20, for example, a multi-layer film of ten layers including the TMR element 22 is formed on a substrate 21. The nine layers form a multi-layer film structure from a first layer (Ta layer), which is the lowest layer, to a tenth layer (Ru Layer), which is the uppermost layer. Specifically, a PtMn layer 24, a CoFe layer 25, a nonmagnetic metal layer (Ru layer) 26, a CoFeB layer 221, a nonmagnetic polycrystalline MgO layer 222, which is a tunnel barrier layer, a CoFeB layer 2232, and a NiFeB layer 2231, are formed. A nonmagnetic Ta layer 27 and a nonmagnetic Ru layer 28 are formed thereon in this order. In FIG. 2, a numeric value in parentheses of each layer indicates the thickness of the layer and the unit thereof is nanometer. The thickness of each layer is just an illustrative example, and the invention is not limited thereto.

In the invention, a ferromagnetic layer 221 may have a laminated structure of two or more layers including a CoFeB layer and other ferromagnetic layers.

Reference numeral 21 denotes a substrate, such as a silicon substrate, a ceramic substrate, a glass substrate, or a sapphire substrate.

Reference numeral 22 denotes a TMR element which is a laminated structure of the ferromagnetic layer 221 made of polycrystalline CoFeB, the tunnel barrier layer 222 made of polycrystalline MgO, the ferromagnetic layer 2232 made of polycrystalline CoFeB, and the ferromagnetic layer 2231 made of polycrystalline NiFeB.

In the invention, the CoFeB ferromagnetic layer 2232 may contain a very small amount of other atoms, such as Pt, Ni, and Mn atoms (5 atomic % or less, preferably, in the range of 0.01 atomic % to 1 atomic %). The content of Ni atoms in the CoFeB ferromagnetic layer 2232 containing Ni atoms as a minor component is 5 atomic % or less, preferably, in the range of 0.01 atomic % to 1.0 atomic % with respect to the content of Ni atoms in the NiFeB ferromagnetic layer 2231.

In the invention, the NiFeB ferromagnetic layer 2231 may contain a very small amount of other atoms, such as Pt, Co, and Mn atoms (5 atomic % or less, preferably, in the range of 0.01 atomic % to 1 atomic %). The content of Co atoms in the NiFeB ferromagnetic layer 2232 containing Co atoms as a minor component is 5 atomic % or less, preferably, in the range of 0.01 atomic % to 1.0 atomic % with respect to the content of Co atoms in the CoFeB ferromagnetic layer 2232.

Reference numeral 23 denotes a lower electrode layer (base layer), which is the first layer (Ta layer), and reference numeral 24 denotes an antiferromagnetic layer, which is the second layer (PtMn layer). Reference numeral 25 denotes a ferromagnetic layer, which is the third layer (CoFe layer), and reference numeral 26 denotes a nonmagnetic layer for exchange coupling, which is the fourth layer (Ru layer).

The fifth layer is a ferromagnetic layer, which is the crystalline CoFeB layer 221. The content of B in the crystalline CoFeB layer 221 is in the range of 0.1 atomic % to 60 atomic %, preferably, in the range of 10 atomic % to 50 atomic %. In the invention, the crystalline CoFeB layer 221 may contain a very small amount of other atoms, such as Pt, Ni, and Mn atoms (5 atomic % or less, preferably, in the range of 0.01 atomic % to 1 atomic %).

The third layer, the fourth layer, and the fifth layer form a magnetization fixed layer 29. The substantial magnetization fixed layer 29 is the ferromagnetic layer, which is the fifth crystalline CoFeB layer 221.

The sixth layer 222 is a polycrystalline MgO tunnel barrier layer, which is an insulating layer. The tunnel barrier layer 222 used in the invention may be a single polycrystalline MgO layer.

The polycrystalline MgO layer in the tunnel barrier layer 222 according to the exemplary embodiment of the invention may contain various kinds of minor components. For example, the polycrystalline MgO layer may contain 10 ppm to 100 ppm of Zn atoms, C atoms, Al atoms, and Ca atom.

The content of B atoms in the polycrystalline MgO of the tunnel barrier layer 222 according to the exemplary embodiment of the invention may be in the range of 1 mass % to 50 mass %, preferably, in the range of 10 mass % to 25 mass %.

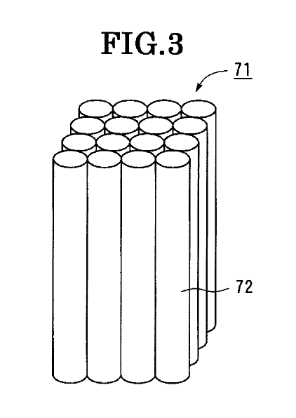

FIG. 3 is a perspective view schematically illustrating a polycrystalline structure including an aggregate 71 of columnar crystals 72 in the MgO layer. The polycrystalline structure also contains a structure of a polycrystalline-amorphous mixture region having a partial amorphous region in a polycrystalline region. It is preferable that each columnar crystal be a single crystal in which the (001) crystal plane is preferentially arranged in the thickness direction. The average diameter of the columnar single crystals is preferably 10 nm or less, more preferably, in the range of 2 nm to 5 nm. The thickness of the columnar single crystal is preferably 10 nm or less, more preferably, in the range of 0.5 nm to 5 nm.

The MgO used in the invention is represented by the following formula:

MgO_{y}O_{z}(0.7≦Z/Y≦1.3, preferably, 0.8≦Z/Y<1.0).

In the invention, it is preferable to use a stoichiometric amount of MgO. However, oxygen-defective MgO may be used to obtain a high MR ratio.

The seventh layer and the eighth layer may function as a magnetization free layer.

The crystalline CoFeB layer 2232, which is the seventh layer, maybe formed by a sputtering method using a CoFeB target. The crystalline NiFeB layer 2231, which is the eighth layer, may be formed by a sputtering method using a NiFeB target.

The crystalline CoFeB layer 221, the crystalline CoFeB layer 2232, and the crystalline NiFeB layer 2231 may have the same crystal structure as that including the aggregate 71 of the columnar crystals 72 shown in FIG. 3.

It is preferable that the crystalline CoFeB layer 221 and the crystalline CoFeB layer 2232 be provided adjacent to the tunnel barrier layer 222 arranged therebetween. The three layers are sequentially laminated in the manufacturing apparatus without breaking vacuum.

Reference numeral 27 denotes an electrode layer, which is the ninth layer (Ta layer).

Reference numeral 28 denotes a hard mask layer, which is the tenth layer (Ru layer). When the tenth layer is used as a hard mask, it may be removed from the magnetoresistance element.

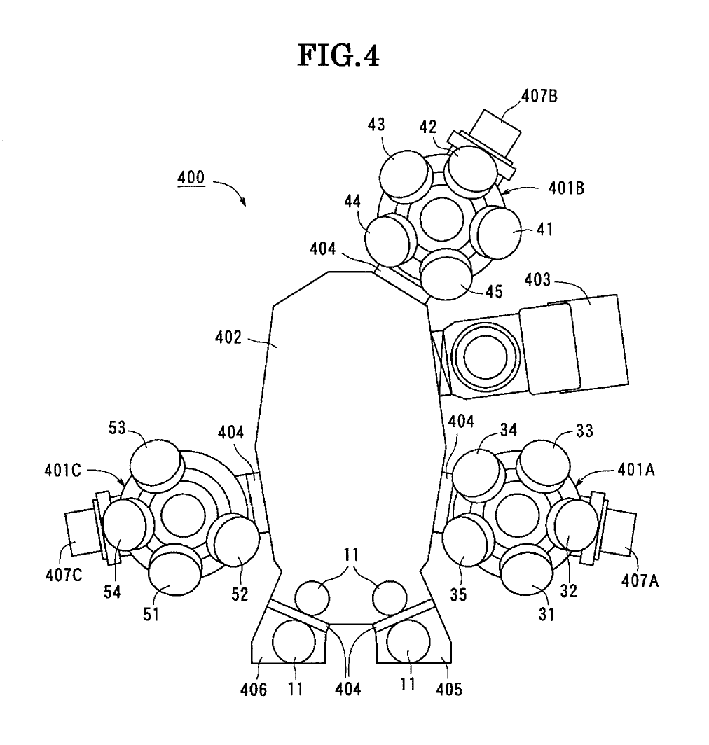

Next, a method and apparatus for manufacturing the magnetoresistance element 20 having the above-mentioned laminated structure will be described with reference to FIG. 4. FIG. 4 is a plan view schematically illustrating an apparatus for manufacturing the magnetoresistance element 20. The apparatus is a sputtering apparatus for mass production that is capable of manufacturing a multi-layer film including a plurality of magnetic layers and nonmagnetic layers.

A magnetic multi-layer film manufacturing apparatus 400 shown in FIG. 4 is a cluster-type manufacturing apparatus and includes three film forming chambers based on a sputtering method. In the apparatus 400, a transport chamber 402 having a robot transport apparatus (not shown) is provided at the center. The transport chamber 402 of the manufacturing apparatus 400 for manufacturing the magnetoresistance element is provided with two load lock and unload lock chambers 405 and 406 by which a substrate (for example, a silicon substrate) 11 is carried in and out. It is possible to reduce the tact time and manufacture a magnetoresistance element with high yield by alternately carrying the substrate in or out from the transport chamber using the load lock and unload lock chambers 405 and 406.

In the manufacturing apparatus 400 for manufacturing the magnetoresistance element, three film-forming magnetron sputtering chambers 401A to 401C and one etching chamber 403 are provided around the transport chamber 402. The etching chamber 403 etches a predetermined surface of the TMR element 20. Gate valves 404 are openably provided between the transport chamber 402 and the chambers 401A to 401C and 403. Each of the chambers 401A to 401C and 402 is provided with, for example, an evacuation mechanism, a gas introduction mechanism, and a power supply mechanism (not shown). The film-forming magnetron sputtering chambers 401A to 401C can sequentially deposit the first to tenth layers on the substrate 11 using a radio frequency sputtering method, without breaking vacuum.

Five cathodes 31 to 35, five cathodes 41 to 45, and four cathodes 51 to 54 are arranged on appropriate circumferences of the ceilings of the film-forming magnetron sputtering chambers 401A to 401C, respectively. The substrate 11 is arranged on a substrate holder that is provided coaxially with the circumference. It is preferable to use a magnetron sputtering apparatus in which magnets are provided on the rear surfaces of targets mounted on the cathodes 31 to 35, the cathodes 41 to 45, and the cathodes 51 to 54.

In the apparatus, power supply units 407A to 407C apply high-frequency power, such as radio frequency power (RF power), to the cathodes 31 to 35, the cathodes 41 to 45, and the cathodes 51 to 54, respectively. As the radio frequency power, a frequency of 0.3 MHz to 10 GHz, preferably, 5 MHz to 5 GHz, and a power of 10 W to 500 W, preferably, 100 W to 300 W may be used.

In the above-mentioned structure, for example, a Ta target is mounted on the cathode 31, a PtMn target is mounted on the cathode 32, a CoFeB target is mounted on the cathode 33, a CoFe target is mounted on the cathode 34, and a Ru target is mounted on the cathode 35.

In addition, a MgO target is mounted on the cathode 41. In addition, a Mg (metal magnesium) target may be mounted on the cathode 42, if necessary. The cathode 42 may be used to provide a metal magnesium layer in the tunnel barrier layer 222.

A CoFeB target for the seventh layer is mounted on the cathode 51, and a Ta target for the ninth layer, which is the Ta layer, is mounted on the cathode 52. In addition, a Ru target for the tenth layer is mounted on the cathode 53, and a NiFeB target for the eighth layer is mounted on the cathode 54.

The in-plane direction of each of the targets is not parallel to the in-plane direction of the substrate at a predetermined angle θ therebetween. When the non-parallel arrangement is used, it is possible to effectively deposit a magnetic film and a nonmagnetic film with the same composition as a target composition by performing sputtering while rotating a target with a diameter smaller than that of the substrate.

According to the exemplary embodiment of the invention, it is possible to change the amorphous state of each of the fifth layer (CoFeB layer 221) , the seventh layer (CoFeB layer 2232), and the eighth layer (NiFeB layer 2231) immediately after being formed into the polycrystalline structure shown in FIG. 3 using an annealing process. Therefore, in the invention, it is possible to carry the formed magnetoresistance element 20 immediately in an annealing furnace (not shown) and perform annealing for transformation of the phase of each of the fifth layer (CoFeB layer 221), the seventh layer (NiFe layer 2232), and the eighth layer (NiFeB layer 2231) from an amorphous state to a crystalline state. In this case, it is possible to magnetize the PtMn layer 24, which is the second layer.

### EXAMPLES

The magnetoresistance element shown in FIG. 2 was manufactured by the film forming apparatus shown in FIG. 4. In particular, the tunnel barrier layer was manufactured by the apparatus shown in FIG. 1.

The deposition conditions of a TMR element 12, which was a main component, were as follows.

The CoFeB layer 221 was formed using a target with a CoFeB composition ratio (atomic:atom ratio) of 60/20/20 at an Ar gas (sputtering gas) pressure of 0.03 Pa. The CoFeB layer 221 was formed by a magnetron DC sputtering (chamber 401A) at a sputtering rate of 0.64 nm/sec. In this case, the CoFeB layer 221 had an amorphous structure.

Then, the sputtering apparatus was replaced with another sputtering apparatus (chamber 401B), and a MgO film was formed using a MgO target that has a relative density shown in the following Table 1 and a composition ratio (atomic:atom ratio) of 50/50.

TABLE 1

Target

| | Relative density of MgO (%) | D/d |
|---|---|---|
| Comparative example 1 | 85.5 | 1/2 |
| Comparative example 2 | 88.5 | 1/1 |
| Comparative example 3 | 88.5 | 1/2 |
| Example 1 | 90.5 | 1/2 |
| Example 2 | 90.5 | 1/1 |
| Example 3 | 95.2 | 1/2 |
| Example 4 | 98.7 | 1/2 |
| Example 5 | 99.9 | 1/2 |

In Comparative example 2 and Example 2, a large film-forming chamber was used.

In Comparative example 2 and Example 2, the MgO target mounted on the cathode 41 had a large diameter satisfying D/d =1. In the other Examples and Comparative examples, the MgO target mounted on the cathode 41 had a small diameter satisfying D/d=0.50. In this example, the angle θ was set to 35°, and the line 114 extending in the plane direction of the substrate and the central axis line 113 of the target 102 intersected each other at a position that was separated by d×(½) from the outer circumference 115 of the substrate 103. In addition, the rotational speed of the substrate support holder 103 was set to 100 rpm.

The tunnel barrier layer 222, which was the MgO layer as the sixth layer, was formed by magnetron RF sputtering (13.56 MHz) at an Ar gas (sputtering gas) pressure of 0.2 Pa in the preferable range of 0.01 Pa to 0.4 Pa. In this case, the MgO layer 222 had a polycrystalline structure including the aggregate 71 of the columnar crystals 72 shown in FIG. 3. In addition, the deposition rate of the magnetron RF sputtering (13.56 MHz) was 0.14 nm/sec. However, the deposition rate may be in the range of 0.01 nm/sec to 1.0 nm/sec.

Then, the sputtering apparatus was replaced with another sputtering apparatus (chamber 401C) and a ferromagnetic layer (the CoFeB layer 2232 as the seventh layer), which was a magnetization free layer, was formed. The CoFeB layer 2232 was formed at an Ar gas (sputtering gas) pressure of 0.03 Pa. The CoFeB layer 2232 was formed at a sputtering rate of 0.64 nm/sec. In this case, the CoFeB layer 2232 was formed using a target with a CoFeB composition ratio (atomic:atom ratio) of 40/40/20. Immediately after the CoFeB layer 2232 was formed, it had an amorphous structure.

Then, in the film-forming magnetron sputtering chamber 401C, a ferromagnetic layer, which was a magnetization free layer (the NiFeB layer 2231 as the eighth layer), was formed. The NiFeB layer 2231 was formed at an Ar gas (sputtering gas) pressure of 0.03 Pa. The NiFeB layer 2231 was formed at a sputtering rate of 0.64 nm/sec. In this case, the NiFeB layer 2231 was formed using a target with a NiFeB composition ratio (atomic:atom ratio) of 40/40/20. Immediately after the NiFeB layer 2231 was formed, it had an amorphous structure.

The magnetoresistance element 20 formed by sputtering deposition in each of the film-forming magnetron sputtering chambers 401A, 401B, and 401C was annealed in a heat treatment furnace in a magnetic field of 8 kOe at a temperature of about 300° C. for 4 hours.

As a result, it was found that the amorphous structure of the CoFeB layer 221, the CoFeB layer 2232, and the NiFeB layer 2231 was changed into the polycrystalline structure including the aggregate 71 of the columnar crystals 72 shown in FIG. 3.

The annealing step enables the magnetoresistance element 20 to have the TMR effect. In addition, predetermined magnetization was given to the antiferromagnetic layer 24, which was the PtMn layer as the second layer, by the annealing

The MR ratios of eight TMR elements manufactured using the targets shown in Table 1 were measured. The measurement results are shown in the following Table 2. Table 2 shows numeric values when the MR ratio of the TMR element according to Comparative example 1 is blank ‘1’.

TABLE 2

| | MR ratio |
|---|---|
| Comparative example 1 | 1 |
| Comparative example 2 | 1 |
| Comparative example 3 | 1.2 |
| Example 1 | 20.5 |
| Example 2 | 22.5 |
| Example 3 | 35.5 |
| Example 4 | 50.5 |
| Example 5 | 60.5 |

The MR ratio is a parameter related to the magnetoresistive effect in which, when the magnetization direction of a magnetic film or a magnetic multi-layer film varies in response to an external magnetic field, the electric resistance of the film is also changed. The rate of change of the electric resistance is used as the rate of change of magnetoresistance (MR ratio).

In Comparative example 4, a TMR element was manufactured by the same method as described above except that the target according to Example 8 was used, the angle θ was 0° when a MgO film was formed, and the rotational speed of the substrate 103 was 0 rpm, and the MR ratio of the TMR element was measured. As a result, the MR ratio was 1/10 or less of the MR ratio according to Example 5.

In Comparative example 5, a TMR element was manufactured by the same method as described above except that the target according to Example 8 was used and the rotational speed of the substrate 103 was 0 rpm, and the MR ratio of the TMR element was measured. As a result, the MR ratio was 1/10 or less of the MR ratio according to Example 5.

In Comparative example 6, a TMR element was manufactured by the same method as described above except that the target according to Example 8 was used and the angle θ was 0°, and the MR ratio of the TMR element was measured. As a result, the MR ratio was 1/10 or less of the MR ratio according to Example 5.

### DESCRIPTION OF REFERENCE NUMERALS AND SIGNS

100: Sputtering cathode

101: Sputtering deposition chamber

102: Target

103: Substrate

104: Substrate support holder

105: Rotating mechanism

106: Rotating shaft

107: Power supply mechanism

108: Computer

109: Input/output unit

110: Storage medium

111: Central processing unit (CPU)

112: Central normal line of substrate 103

113: Central normal line of target 102

114: Line extending in plane direction of substrate 103

115: Outer circumference of substrate close to target

116: Center of substrate 103

117: Center of target 102

20: Magnetoresistance element

21: Substrate

22: TMR element

221: CoFeB ferromagnetic layer (fifth layer)

222: Tunnel barrier layer (sixth layer)

2231: NiFeB ferromagnetic layer (eighth layer; magnetization free layer)

2231: CoFeB ferromagnetic layer (seventh layer; magnetization free layer)

23: Lower electrode layer (first layer; base layer)

24: Antiferromagnetic layer (second layer)

25: Ferromagnetic layer (third layer)

26: Nonmagnetic layer for exchange coupling (fourth layer)

27: Upper electrode layer (ninth layer)

28: Hard mask layer (tenth layer)

29: Magnetization fixed layer

400: Magnetoresistance element manufacturing apparatus

401A to 401C: Film forming chamber

402: Transport chamber

403: Etching chamber

404: Gate valve

405, 406: Load lock and unload lock chamber

31 to 35, 41 to 45, 51 to 54: Cathode

407A to 407C: Power supply unit

71: Aggregate of columnar crystals

72: Columnar crystal

1. A method of manufacturing a magnetoresistance element comprising:
a step of forming a magnetization fixed layer, a magnetization free layer, and a tunnel barrier layer provided between the magnetization fixed layer and the magnetization free layer on a substrate using a sputtering method,
wherein the step of forming the tunnel barrier layer includes a step of forming a crystalline magnesium oxide layer by the sputtering method using a target which contains a magnesium oxide sintered body and has a relative density of 90% or more.

2. The method of manufacturing a magnetoresistance element according to claim 1, wherein the relative density of the target is in the range of 95.0% to 99.9%.

3. The method of manufacturing a magnetoresistance element according to claim 1, wherein, in the step of forming the tunnel barrier layer, the diameter of the target is smaller than that of the substrate, the target and the substrate are arranged such that a normal line passing through the center of the target intersects a normal line passing through the center of the substrate, and the crystalline magnesium oxide layer is formed by the sputtering method while the substrate is rotated.

4. The method of manufacturing a magnetoresistance element according to claim 3, wherein, in the step of forming the tunnel barrier layer, the substrate is rotated at a rotational speed of 30 rpm or more.

5. (canceled)

6. The method of manufacturing a magnetoresistance element according to claim 3, wherein, in the step of forming the tunnel barrier layer, the normal line passing through the center of the target intersects the normal line passing through the center of the substrate at an angle of 1° to 60°.

7. (canceled)

8. The method of manufacturing a magnetoresistance element according to claim 3, wherein, in the step of forming the tunnel barrier layer, the radius D of the target and the radius d of the substrate satisfy 0.01 d≦D≦0.90 d.

9. (canceled)

10. The method of manufacturing a magnetoresistance element according to claim 3, wherein, in the step of forming the tunnel barrier layer, a line extending in the plane direction of the substrate intersects the normal line passing through the center of the target at a position that is away from the center of the substrate.

11. The method of manufacturing a magnetoresistance element according to claim 10, wherein, in the step of forming the tunnel barrier layer, the line extending in the plane direction of the substrate intersects the normal line passing through the center of the target at a position that is away from the outer circumference of the substrate.

12.-22. (canceled)

23. The method of manufacturing a magnetoresistance element according to claim 1, wherein the sputtering method using the target which contains the magnesium oxide sintered body and has a relative density of 90% or more is performed at a deposition rate of 1 nm/sec or less.

24. The method of manufacturing a magnetoresistance element according to claim 1, wherein the sputtering method using the target which contains the magnesium oxide sintered body and has a relative density of 90% or more is performed at a sputtering gas pressure of 0.4 Pa or less.

25. The method of manufacturing a magnetoresistance element according to claim 1, wherein the sputtering method using the target which contains the magnesium oxide sintered body and has a relative density of 90% or more is performed at a deposition rate of 1 nm/sec or less and a sputtering gas pressure of 0.4 Pa or less.
